(19) United States
(12) Patent Application Publication
(10) Pub. No.: US 2015/0048496 A1
(43) Pub. Date: Feb. 19, 2015

(54) FABRICATION PROCESS AND STRUCTURE TO FORM BUMPS ALIGNED ON TSV ON CHIP BACKSIDE

(71) Applicants: Macrotech Technology Inc., Hsinchu (TW); Powertech Technology Inc., Hsinchu (TW)

(72) Inventors: Chao-Shun CHIU, Hsinchu (TW); Yen-Chu CHEN, Hsinchu (TW)

(73) Assignees: MACROTECH TECHNOLOGY INC., Hsinchu (TW); POWERTECH TECHNOLOGY INC., Hsinchu (TW)

(21) Appl. No.: 13/965,993

(22) Filed: Aug. 13, 2013

(51) Int. Cl. H01L 23/00

(52) U.S. Cl. CPC H01L 24/11; H01L 24/10
USPC 257/737; 438/613

(57) ABSTRACT

Disclosed is a fabrication process of fabricating bumps aligned on TSVs on chip backside. A plurality of TSV pillars are embedded inside the semiconductor layer of an IC substrate where the sidewalls the bottom of the TSV pillars toward the chip backside are covered by a dielectric liner. Then, the thickness of the semiconductor layer is reduced from the chip backside to make the bottom portion of the dielectric liner to be exposed from the chip backside by including a first selectively etching. Then, a backside passivation is disposed on the chip backside without disposing on the bottoms of the TSV pillars. Then, the bottom portion of the dielectric liner is removed by a second selectively etching. An UBM layer is disposed on the backside passivation. A plurality of bumps are disposed on the UBM layer where the interface between each bump and each TSV pillar is a central protrusion lumped toward the corresponding bump. Accordingly, the interfaces between the bumps and the TSV pillars offer an increased bonding area to increase adhesion anchoring effects for the bumps bonded on the UBM layer through the central protrusions.

### FIELD OF THE INVENTION

The present invention relates to a semiconductor device with vertical 3D via interconnection, more specifically to a fabrication process and a structure to form a plurality of bumps aligned on TSV's on chip backside.

### BACKGROUND OF THE INVENTION

Through Silicon Via (TSV) is implemented in advanced interconnections between semiconductor chips to achieve double-side electrical connection for the fabrication of 3D IC stacking assembly to vertically stack more chips with smaller dimensions. 3D IC stacking technology with TSV is able to continue the development of Moore's Law to fulfill smaller IC chips with higher operation speed and lower power consumption. There are three different process options to form TSV, including via-first, via-middle, and via-last processes. In via first processes, TSVs are formed before IC fabrication. In via middle processes, TSVs are formed after IC fabrication and before back end of line (BEOL) processes. In via last processes, TSVs are formed after front end of line (FEOL) and BEOL.

Moreover, micro bumps are needed to form on chip surfaces as the interconnection bonding components between vertically stacked chips. The standard processes to form and align micro bumps on TSV, using via-last processes as an example, are shown as follows: thinning from chip backside, etching chip backside by DRIE to expose the dielectric liner, disposing backside passivation, removing dielectric liner and passivation on the extruded terminals of TSV pillars, disposing an UBM layer by sputtering, and fabricating micro bumps by plating. During disposing backside passivation, backside passivation would also cover the extruded terminals of TSV pillars. In order to expose more extruded terminals of TSV pillars from chip backside, DRIE is implemented where the extruded height ranges from 5 μm to 10 μm or more. If the extruded height is too small, excessive passivation on chip backside would be removed by CMP where the protection and isolation of chip backside by the passivation may not be sufficient. Moreover, CMP processes also polish the extruded terminals of TSV leading to Cu contamination issues. Furthermore, in the conventional structure of fabricating bumps aligned on TSVs on chip backside, the adhesion between bumps and TSV is not enough due to smoother surfaces between bumps and TSV interfaces caused by CMP processes leading to easily-broken bumps.

### SUMMARY OF THE INVENTION

The main purpose of the present invention is to provide a fabrication process and a structure to fabricate bumps aligned on TSVs on chip backside which can be implemented in via-middle processes to increase the adhesion area and the adhesion strength between bumps and TSV where thinning technology of semiconductor layers can be simplified and the thinning thickness can be reduced. During exposing dielectric liner processes, DRIB can be replaced by conventional etching processes. During exposing TSV processes, CMP can be replaced by selective etching to reduce Cu contamination issues and to reduce the thickness of backside passivation as well as the thickness of the UBM layer to achieve fabricating bumps aligned on TSVs on chip backside with lower cost and higher quality.

According to the present invention, a fabrication process to form a plurality of bumps aligned on TSVs on chip backside is revealed, comprising the following steps, firstly, providing an IC substrate having a first surface and a second surface where the first surface is attached to a wafer support system. A plurality of TSV pillars are embedded inside the semiconductor layers of the substrate where the sidewalls and the bottoms of the TSV pillars are covered by a dielectric liner. Then, the thickness of the semiconductor layer is reduced from the second surface to expose the dielectric liner covering on the bottoms of the TSV pillars by including a first selectively etching. Then, a backside passivation is disposed on the second surface without disposing on the bottom terminals of the TSV pillars. Then, the bottom portion of the dielectric liner is removed to expose the bottoms of the TSV pillars by a second selectively etching without etching the backside passivation. Then, an UBM layer is disposed on the backside passivation and is bonded to the bottom terminals of the TSV pillars. Then, a plurality of bumps are disposed on the UBM layer aligned on the TSV pillars where the interface between each bump and each TSV pillar is a central protrusion lumped toward the corresponding bump. A structure of fabricated bumps aligned on TSVs on chip backside is also revealed.

### DESCRIPTION OF THE DRAWINGS

FIGS. 1A to 1J showing component cross-sectional views illustrating the steps of a fabrication process to form a plurality of bumps aligned on TSVs on chip backside according to the preferred embodiment of the present invention.

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

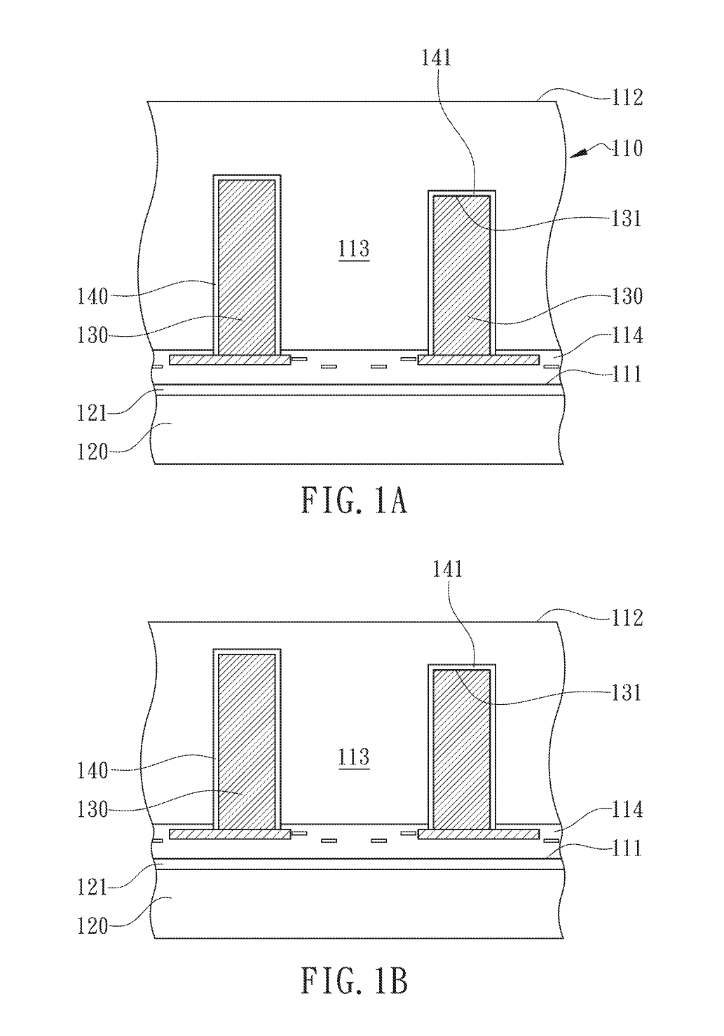

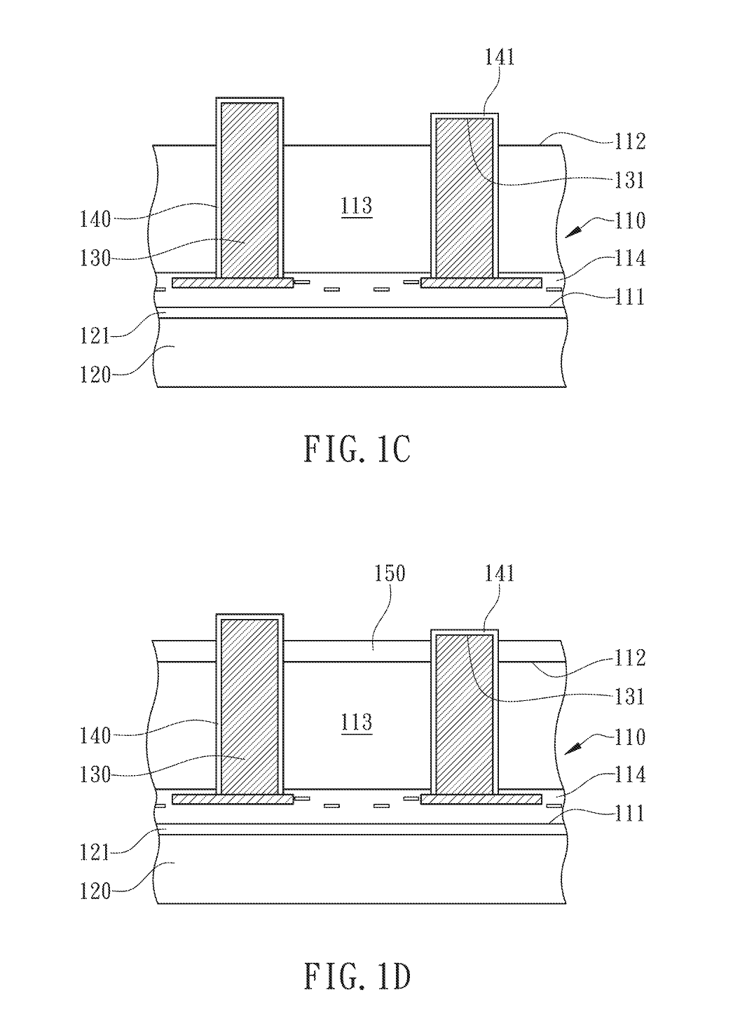

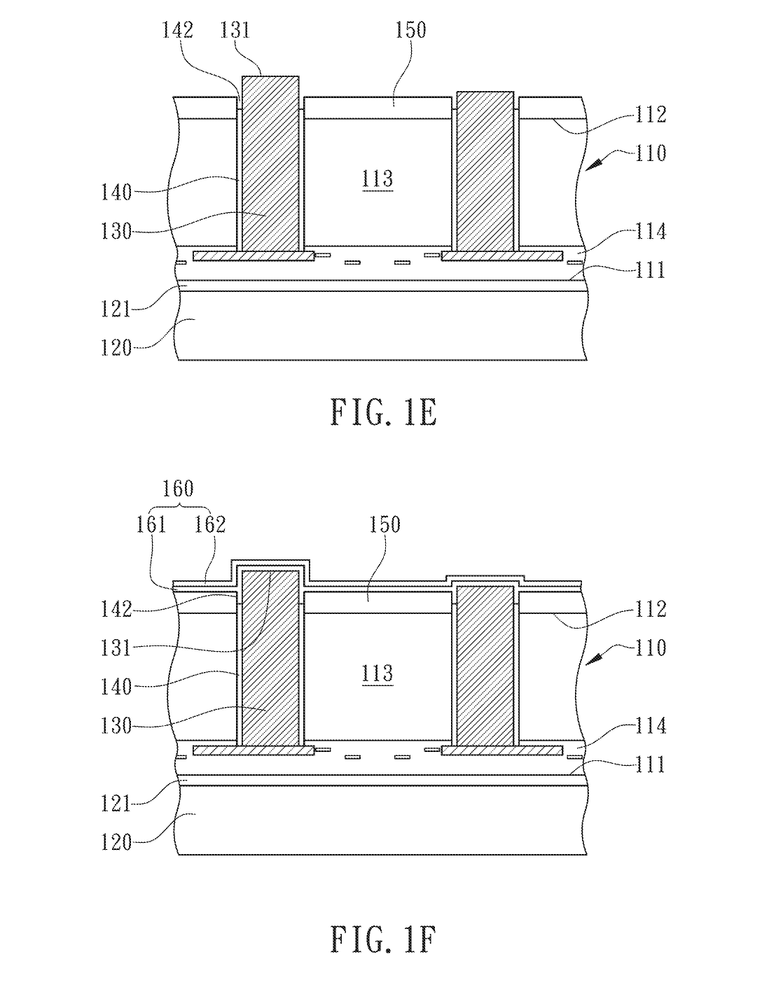

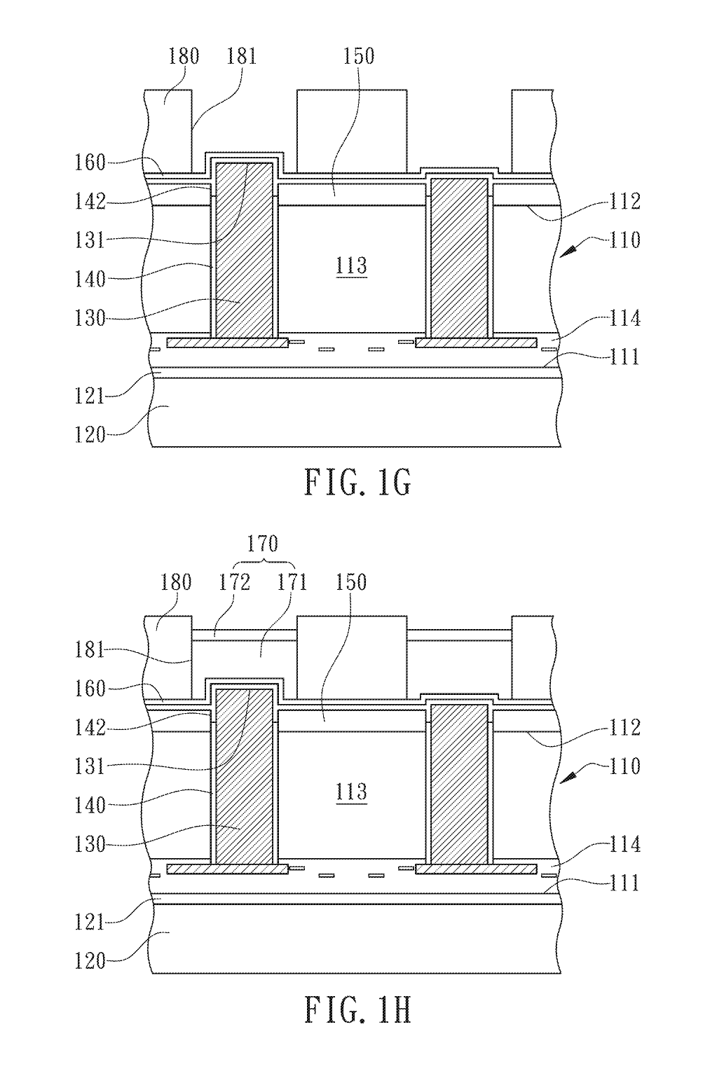

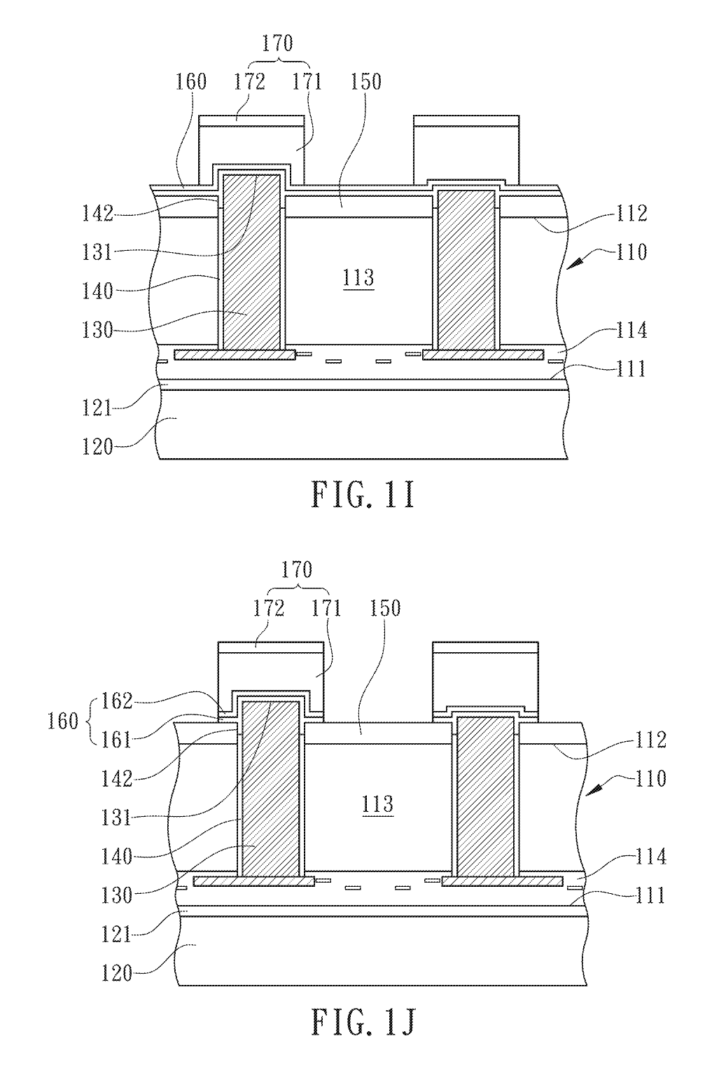

According to the preferred embodiment of the present invention, a process to fabricate bumps aligned on TSVs on chip backside are illustrated from FIG. 1A to FIG. 1J for component cross-sectional views. The processes to fabricate bumps aligned on TSVs on chip backside include the following steps.

Firstly, as shown in FIG. 1A, an IC substrate 110 is provided having a first surface 111 and a second surface 112 where the first surface 111 of the substrate 110 is attached to a wafer support system 120 (WSS). The wafer support system 120 is a wafer carrier with temporary adhesive. The IC substrate 110 means that a semiconductor substrate has integrated circuits on the first surface 111. A plurality of TSV pillars 130 are embedded inside the semiconductor layer 113 of the substrate 110 where a plurality of sidewalls and a plurality of bottoms 131 of the TSV pillars 130 are covered by a dielectric liner 140. The TSV pillars 130 are vertically interconnection components inside the Through Silicon Via (TSV). The substrate 110 can be a semiconductor wafer having gone through via-middle and BEOL IC fabrication processes where the first surface 111 is an active surface with integrated circuits being fabricated. In the present processing step, the second surface 112 is a chip backside without thinning where the thickness of the substrate 110 from the first surface 111 to the second surface 112 is around 775 μm to or more which is much greater than the length of the TSV pillars 130. The material of the TSV pillars 130 can be Cu (copper) or Cu alloy. The material of the dielectric liner 140 can be nitrides or oxides such as silicon nitride or silicon dioxide. The bottoms 131 of the TSV pillars 130 are facing toward the second surface 112. After TSV formation, a backend circuitry 114 is fabricated on the first surface 111 to electrically connect the TSV pillars 130. The wafer support system 120 is adhered to the first surface 111 of the substrate 110 by a temporary adhesive layer 121 to avoid deformation of the substrate 110 during fabrication steps. The wafer support system 120 can be a glass wafer or a silicon wafer where the temporary adhesive layer 121 can be light-sensitive adhesive which will lose its adhesive after UV irradiation to release processing wafers from the wafer support system 120 after fabrication processes. The substrate 110 is always adhered to the wafer support system 120 in the following steps until the finish of the fabrication of bumps 170.

Then, as shown in FIG. 1B, the thickness of the semiconductor layer 113 is reduced from the second surface 112 by including a first selectively etching. The present processing step of reducing the thickness of the semiconductor layer 113 includes a backside thinning step and the first selective etching step where most of the thickness of the semiconductor layer 113 is reduced by a backside thinning step but without exposing the TSV pillars 130 and the dielectric liner 140. As shown in FIG. 1C, the above mentioned first selective etching step is only to etch semiconductor material of the semiconductor layer 113 without etching the dielectric liner 140 which can be a dry etching or a wet etching. For a dry etching, Inductively Coupled Plasma system (ICP) can be implemented where SF6 is filled into the etching chamber as the plasma reaction gas where other gases can also be included such as O₂, Cl₂, Ar, He, HBr, etc. The top power supply of the etching chamber ranges from 500 W to 3000 W and the bottom power supply of the etching chamber ranges from 0 W to 1000 W For a wet etching, the etching solution can be chosen from either KOH or TMAH (Tetramethylammonium Hydroxide) as a basic etching solvent. The thickness of the semiconductor layer 113 from the second surface 112 can further be reduced to expose the dielectric liner 140 covering on the bottoms 131 of the TSV pillars 130. Preferably, the bottoms 131 of the TSV pillars 130 are extruded from the second surface 112. In this process, the TSV pillars 130 can have different extruded heights from the thinned second surface 112, as shown in FIG. 1C. The thickness of the substrate 110 from the first surface 111 to the second surface 112 can further be reduced down to 100 μm or less. The extruded height of the bottoms 131 of the TSV pillars 130 ranges from 1 μm to 5 μm which is lower than the extruded height requirements, 5 μm in to 10 μm, of the conventional DRIE processes without the easily-broken risk between the TSV pillars 130 and the bumps.

Then, as shown in FIG. ID, a backside passivation 150 is selectively disposed on the second surface 112 where the backside passivation 150 does not cover the bottoms 131 of the TSV pillars 130. In the present embodiment, the material of the backside passivation 150 is an organic polymer which is different from the inorganic material of the dielectric liner 140. Preferably, the disposed thickness of the backside passivation 150 is not greater than the extruded height of the TSV pillars 130. The backside passivation 150 would only dispose on the semiconductor layer 113 without disposing on the dielectric liner 140. A more specific method of the above mentioned selective disposition is the wet process of electro-grafting technique, therefore, the backside passivation 150 is not disposed on the dielectric liner 150.

Then, as shown in FIG. 1E, the bottom portion 141 of the dielectric liner 140 are removed to expose the bottoms 131 of the TSV pillars 130 without etching the backside passivation 150 by a second selectively etching so that the metal surface of the TSV pillars 130 is exposed. The above mentioned selective etching by either dry etching or wet etching will only etch the dielectric liner 140 without etching the backside passivation 150. The dry etching method implements ICP system where the etching chamber fills with CF₄ as plasma reaction gas which can further include O₂, C₄F₈, Ar, etc. The top power supply ranges from 300 W to 3000 W and the bottom power supply ranges from 0 W to 2000 W. Alternatively, the wet etching implements a dilute etching solution of HF with 1 to 20 mixing ratio to etch the dielectric liner 140. Therefore, the selective etching does not etch the backside passivation 150. Preferably, the above mentioned processing step of selective etching of the dielectric liner 140, a plurality of indentation rings 142 reentrant from the backside passivation 150 are formed in the dielectric liner 140 on the sidewalls of the TSV pillars 130. Therefore, in the second selectively step of exposing the TSV pillars 130, CMP can be replaced by the selective etching of the dielectric liner 140 without etching the backside passivation 150 and the TSV pillars 130 where Cu contamination and the fabrication cost can greatly be reduced.

Then, as shown in FIG. 1F, an UBM layer 160 is disposed on the backside passivation 150 by sputtering where the UBM layer 160 is bonded to the bottoms 131 of the TSV pillars 130. In the present processing step, the UBM layer 160 includes a barrier layer 161 and a plating seed layer 162 where the material of the barrier layer 161 can be Ti, Ni, TiN, or Ta, etc. to prevent metal migration. The material of the plating seed layer 162 has high conductivity such as Cu, Al, Au, or its alloy or a multi-layer combination. Moreover, during the step of UBM disposition, the UBM layer 160 can preferably fill into the indentation rings 142 to enhance the metal adhesion area and to increase adhesion anchoring effect between the UBM layer 160 and the TSV pillars 130 through protrusions. Furthermore, the depth of the indentation rings 142 can be smaller than the thickness of the backside passivation 150 such as smaller than 5 um to prevent the UBM layer 160 to contact with the semiconductor layer 113.

As shown in FIG. 1G, a photoresist (PR) 180 is disposed on the UBM layer 160 then exposed to develop a plurality of bump openings 181 aligned to the TSV pillars 130. As shown in FIG. 1H, a plurality of bumps 170 can be electroplated on the UBM layer 160 according to the bump openings 181 since the UBM layer 160 is conductive for electroplating where the interface between each bump 170 and each TSV pillar 130 is a central protrusion lumped toward the corresponding bump 170. The above mentioned protrusion will become hollow according to the extruded height of the TSV pillars 130. In the present embodiment, each bump 170 includes a copper pillar bump 171 and a solder cap 172 which can be fabricated within the same plating processes with the same PR pattern.

As shown in FIG. 1I, PR 180 is stripped by PR stripping processes to expose the UBM layer 160 outside the bumps 170. As shown in FIG. 1J, the exposed UBM layer 160 outside the bumps 170 is removed by UBM etching. Therefore, according to the above mentioned process flow, a structure with bumps aligned on TSVs on chip backside is fabricated.

Therefore, the present invention provides a process flow and a structure to fabricate bumps aligned on TSVs on chip backside to increase the interface adhesion area and to increase adhesion anchoring effect between the UBM layer and the TSV pillars through protrusions to simplify the semiconductor material thinning technique and to reduce thinning thickness. During the thinning processes to expose the dielectric liner, DRIE processes can be replaced by conventional etching processes. During the exposing processes of TSV, CMP processes can be replaced by conventional selective etching processes of dielectric liner to avoid Cu contamination and to reduce the thickness of the backside passivation and the thickness of the UBM layer to achieve lower cost with higher quality in fabrication of bumps at bottoms.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. A fabrication process to form a plurality of bumps aligned on TSVs on chip backside, comprising the steps of:
providing an IC substrate having a first surface and a second surface, wherein the first surface is attached to a wafer support system and a plurality of TSV pillars are embedded inside a semiconductor layer of the substrate, wherein a plurality of sidewalls and a plurality of bottoms of the TSV pillars toward the second surface are covered by a dielectric liner;
reducing the thickness of the semiconductor layer from the second surface to expose the dielectric liner covering on the bottoms of the TSV pillars by including a first selectively etching;
disposing a backside passivation on the second surface, wherein the backside passivation is not disposed on the bottoms of the TSV pillars;
removing the dielectric liner exposed on the bottoms of the TSV pillars to expose the bottoms of the TSV pillars without etching the backside passivation by a second selectively etching;
disposing an UBM layer on the backside passivation, wherein the UBM layer is bonded with the bottoms of the TSV pillars; and
disposing a plurality of bumps on the UBM layer aligned on the TSV pillars, wherein the interface between each bump and each TSV pillar is a central protrusion lumped toward the corresponding bump.

2. The fabrication process as claimed in claim 1, wherein a plurality of indentation rings reentrant from the backside passivation are formed in the dielectric liner on the sidewalls of the TSV pillars during the step of removing the dielectric liner, and the UBM layer fills into the indentation rings during the step of forming the UBM layer.

3. The fabrication process as claimed in claim 2, wherein the depth of the indentation rings is smaller than the thickness of the backside passivation.

4. The fabrication process as claimed in claim 2, wherein the step of reducing the thickness of the semiconductor layer further includes a backside thinning step before the first selective etching step, wherein the bottoms of the TSV pillars extruded from the second surface.

5. The fabrication process as claimed in claim 4, wherein the TSV pillars have different extruded heights from the second surface.

6. The fabrication process as claimed in claim 2, wherein the UBM layer includes a barrier layer and a plating seed layer.

7. The fabrication process as claimed in claim 1, wherein the material of the backside passivation is an organic polymer different from the inorganic material of the dielectric liner.

8. The fabrication process as claimed in claim 1, wherein each bump includes a copper pillar bump and a solder cap.

9. A structure of forming a plurality of bumps aligned on TSVs on chip backside, comprising:
an IC substrate having a first surface and a second surface, wherein a plurality of TSV pillars are embedded inside a semiconductor layer of the substrate, wherein a plurality of sidewalls of the TSV pillars are covered by a dielectric liner;
a backside passivation disposed on the second surface, wherein the backside passivation is not disposed on the bottoms of the TSV pillars;
an UBM layer formed on the backside passivation and bonded to the bottoms of the TSV pillars; and
a plurality of bumps formed on the UBM layer, where the interface between each bump and each TSV pillar is a central protrusion lumped toward the corresponding bump.

10. The structure as claimed in claim 9, wherein a plurality of indentation rings reentrant from the backside passivation are formed in the dielectric liner on the sidewalls of the TSV pillars, wherein the UBM layer fills into the indentation rings.

11. The structure as claimed in claim 10, wherein the bottoms of the TSV pillars are extruded from the second surface.

12. The structure as claimed in claim 11, wherein the TSV pillars have different extruded heights from the second surface.

13. The structure as claimed in claim 10, wherein the UBM layer includes a barrier layer and a plating seed layer.

14. The structure as claimed in claim 9, wherein the material of the backside passivation is an organic polymer different from the inorganic material of the dielectric liner.

15. The structure as claimed in claim 9, wherein each bump includes a copper pillar bump and a solder cap.
